(19) United States
(12) Patent Application Publication
(10) Pub. No.: US 2026/0100410 A1
(43) Pub. Date: Apr. 9, 2026

(54) SELF-HEALING PRINTED SOLID STATE BATTERY

(71) Applicant: INTERNATIONAL BUSINESS MACHINES CORPORATION, Armonk, NY (US)

(72) Inventors: Aaron Keith Baughman, Cary, NC (US); Sarbajit Kumar Rakshit, Kolkata (IN); Jeremy R. Fox, Georgetown, TX (US); Kavitha Hassan Yogaraj, Bangalore (IN)

(21) Appl. No.: 18/907,958

(22) Filed: Oct. 7, 2024

(51) Int. Cl. H01M 10/0562; G01R 31/367; G01R 31/385; H01M 10/0585

(52) U.S. Cl. CPC H01M 10/0562; G01R 31/367; G01R 31/3865; H01M 10/0585

(57) ABSTRACT

A computer-implemented method for fabricating a solid state battery includes identifying locations in a solid-state battery where defects are likely to occur. A self-healing material profile is determined relative to solid-state battery component material to counter defect growth in the locations. The solid-state battery is printed in accordance with the self-healing material profile.

### BACKGROUND

The present invention generally relates to solid state batteries and, more particularly, to batteries with self-healing capabilities to extend life and to prevent cracking.

A lithium-ion battery is composed of a cathode, anode, separator and electrolyte. A lithium-ion battery for smartphones, power tools and electric vehicles (EVs) employs liquid electrolyte batteries. A solid-state battery uses a solid electrolyte, not liquid/gel. Solid-state batteries have greater energy storage density, have increased reliability and wear resistance, and are faster charging.

At high temperatures, liquid electrolytes can become volatile and flammable. While solid electrolytes have improved thermal stability, which limits the risk of fire or explosion, impact or mechanical stress can cause damage to a solid-state battery electrolyte cell. Applied impact shocks on a battery can result in dendrite formation, and with additional shock or stress, cracking can occur. Cracks can lead to significant loss of efficiency up to catastrophic battery failure.

### SUMMARY

In accordance with an embodiment of the present invention, a computer-implemented method for fabricating a solid state battery includes identifying locations in a solid-state battery where defects are likely to occur. A self-healing material profile is determined relative to solid-state battery component material to counter defect growth in the locations. The solid-state battery is printed in accordance with the self-healing material profile.

In accordance with another embodiment of the present invention, a system for fabricating a solid state battery includes a hardware processor and a memory that stores a computer program which, when executed by the hardware processor causes the hardware processor to identify locations in a solid-state battery where defects are likely to occur; determine a self-healing material profile relative to solid-state battery component material to counter defect growth in the locations; and print the solid-state battery in accordance with the self-healing material profile.

In accordance with another embodiment of the present invention, a solid-state battery includes an anode, a cathode and a solid-state electrolyte disposed between the anode and the cathode. The solid-state electrolyte includes self-healing material to repair defects therein.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a block diagram of a system for designing and fabricating a self-healing solid-state battery and training and employing a historical learning model, in accordance with an embodiment of the present invention;

FIG. 2 is a schematic cross-section diagram showing a solid-state battery having defects to be addressed in accordance with an embodiment of the present invention;

FIG. 3 is a schematic cross-section diagram showing a solid-state battery having self-healing regions, in accordance with an embodiment of the present invention;

FIG. 4 is a schematic cross-section diagram showing a solid-state battery after defects have been self-healed, in accordance with an embodiment of the present invention;

FIG. 5 is a block/flow diagram showing another system for making a self-healing solid-state battery, in accordance with an embodiment of the present invention;

FIG. 6 is a block/flow diagram showing another system for managing self-healing in a pack of batteries, in accordance with an embodiment of the present invention;

FIG. 7 is a block/flow diagram showing another system for addressing defects using a neural network for a self-healing solid-state battery, in accordance with an embodiment of the present invention;

FIG. 8 is a block/flow diagram showing another system for fabricating a self-healing solid-state battery, in accordance with an embodiment of the present invention; and

FIG. 9 is a flow diagram showing methods for designing and fabricating a solid-state battery having self-healing features, in accordance with an embodiment of the present invention.

### DETAILED DESCRIPTION

In accordance with embodiments of the present invention, a battery fabrication system is described that identifies and integrates appropriate self-healing measures within a solid-state battery and its components. A solid-state battery includes, as components, a cathode, an anode, solid-state electrolyte, an electrolyte/anode interface, an electrolyte/cathode interface and structural surroundings. In embodiments, systems and methods are described for three-dimensional (3D) printing a solid-state battery composition with self-healing capabilities that utilizes historical learning regarding structure and material properties of a cathode, an anode and an electrolyte. The systems and methods identify potential crack growth mechanisms and locations due to battery usage and operational stresses. A pattern of dendrite and/or crack formation can be predicted using artificial intelligence to determine a response of the battery, e.g., over multiple recharging cycles, based on the historical learning. In response to a determination that a crack or dendrite will form (e.g., in the electrolyte), an appropriate proportion of a solid-state electrolyte material and a self-healing material is determined for the fabrication of a battery. The solid-state electrolyte material and the self-healing material can be mixed in accordance with the appropriate proportion in a mixing chamber. A solid-state battery can be 3D printed with the appropriate proportion of the solid-state electrolyte material and the self-healing material.

Types of self-healing materials that can be employed in accordance with embodiments of the present invention can include, e.g., thermoplastic polymers, polyurethane and epoxy composites, microencapsulated self-healing materials, conductive self-healing materials, etc. These materials can employ one or more processes by which self-healing occurs. For example, self-healing can occur by chemical reactions, physical reconfiguration, capillary action, microcapsule rupture, phase change mechanisms, etc.

The systems and methods can evaluate potential dendrite formation on the 3D printed battery and determine a time for the self-healing material to grow within the crack during use. A maximum recharge and discharge rate can be determined based on the dendrite formation on the 3D printed battery. The 3D printed battery can be selected for recharge in response to determining that the self-healing material growth is complete. The self-healing material can be employed for healing in response to a determination that there is a crack in the electrolyte or other component of the battery. The pattern of the dendrite formation can be predicted by creating a 3D model of dendrite formation and selecting the appropriate proportion of the solid-state electrolyte material and the self-healing material based on the 3D model.

In an embodiment, the battery design system analyzes operational parameters, solid-state electrodes, electrolyte materials, and potential stresses that may propagate through the battery. The system can execute, e.g., a digital twin simulation to identify structures defects, dendrites, cracks, etc. The systems and methods can integrate a generative adversarial network (GAN) to create a dynamic battery necessary for a space, size, and other physical requirements for the print of the solid-state battery. Structural weakness can be determined by running through a life cycle of the solid-state battery under operational conditions or taking actions and activities of the expected device under a factor of safety.

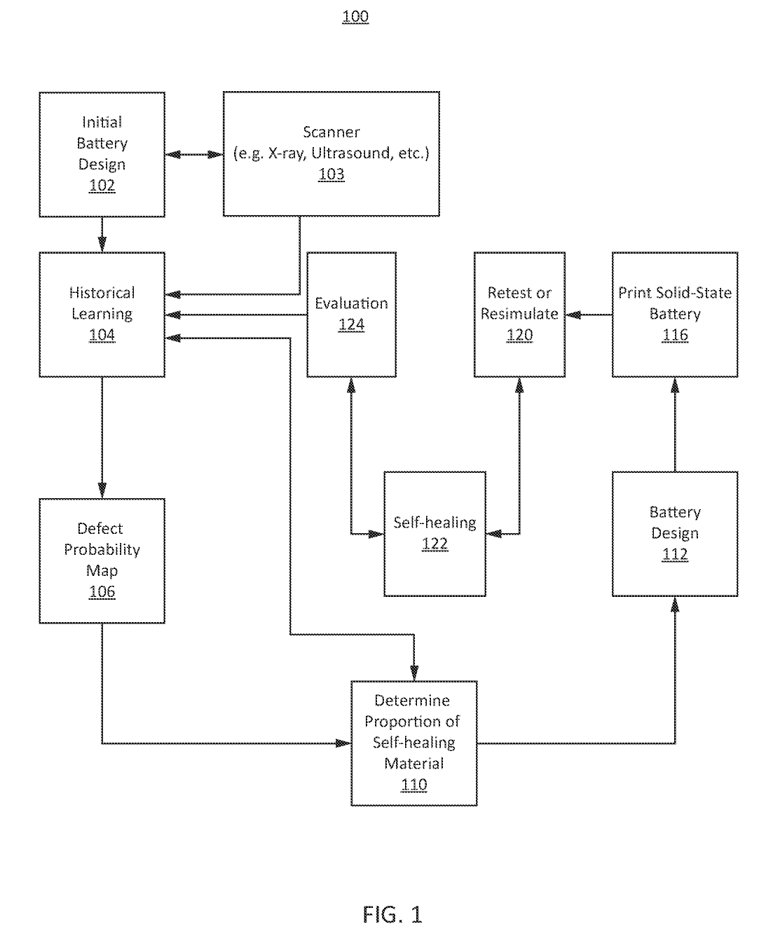

Referring now to the drawings in which like numerals represent the same or similar elements and initially to FIG. 1, a system 100 for designing and fabricating solid-state batteries with self-healing capabilities is shown in accordance with embodiments of the present invention. In an embodiment, the system 100 begins with an initial design 102 and analyzes operational parameters, structural features, materials, and potential stresses that may propagate cracks or dendrites through a solid-state battery design. The solid-state battery design can include an existing battery design or a proposed battery design. The battery design can include a computer aided design model or include images or scans of the solid-state battery design. The type or types of input that the system 100 can employ depends on training data employed to train a neural network model.

In an embodiment a neural network model is trained based on historic battery data. The training data can include scans or images of cross-sectional views of solid-state batteries that have experienced degradation over time. Cracks, dendrites and other fail mode mechanisms should be visible to train a historical learning model 104. The system 100 can employ the historical learning model 104 to identify potential defects in the design, predict the type of defects and predict a position of the defect(s). In an example, data collected over a period of time for a given initial design (or similar designs) can be employed to train the historical learning model 104.

The training data can include, e.g., X-ray images, ultrasound images or other images or data regarding crack propagation, spallation and/or dendrites or other defects that could emerge within a structure of the battery. Based on historically gathered images of X-ray, ultrasound, etc. of the solid-state battery based on numbers of recharge cycles for various battery specifications, a dendrite formation model can be created. A scanning module or system 103 can be employed to validate an internal structure of a solid-state battery and can be employed to record how the internal structure changes after every recharge or over time. The deterioration cycling can be added or include in an adjoined knowledge corpus of a historical learning model 104.

Using the historical learning model 104, material properties of the cathode, anode and electrolyte, gap between cathode and anode, etc. will be understood sufficiently to make predictions about defect probability output 106 for patterns of crack or dendrite formation. The historical learning model 104 will identify trends and probabilities for defect formation. For example, in a solid-state battery cracks are more likely to begin at an interface between an anode and the solid electrolyte, which can gradually form on the anode over multiple recharging cycles. In this way, the region of the solid-state battery in the solid-state electrolyte at the anode side would have a higher likelihood of propagating defects than other portions of the battery.

Using the historical learning model 104, predictions as to the type, extent and locations within the solid-state battery design can be determined as a defect probability output 106. The defect probability output 106 can take the form of a probability map (or map) for defects and potential crack growth or dendrite growth under a particular set of conditions. For example, if the battery is to undergo 10,000 recharge cycles, a probability map of, say, a cross-section of the battery, can be output showing potential cracking, dendrite growth etc., over the 10,000 cycles. The map shows vulnerable regions of the battery that can be linked to charge flow, stress fields, design features (e.g., interfaces between components), etc.

For a given solid-state battery design, regions or portions of the design are considered to determine whether a defect or damage is likely at a particular position. For example, the system 100 can traverse a grid area one space at a time in the grid and compare a grid position to the probability map from the defect probability output 106. If a defect is likely, the system 100 determines an appropriate proportion of self-healing material to replace battery component material in the design of the battery in block 110. For example, at the interface of the anode and the solid-state electrolyte the self-healing materials can include, e.g., a 25% proportion where a central portion of the solid-state electrolyte can include a 5% proportion of self-healing material. The proportion of materials and a distribution of the self-healing material are determined in block 110. Block 110 can employ the historical learning model 104 to determine an optimized self-healing material configuration for a particular battery design. In this capacity, training data indicating the success of a self-healed battery in accordance with different distributions of self-healing material can be employed. The training can include metrics for a successful self-heal. For example, how additional recharge cycles were achieved with a particular distribution of self-healing material with a particular proportion of self-healing material. In an embodiment, the proportion of self-healing material can be provided as a mixture of self-healing material and solid-state battery component material (e.g., solid-state electrolyte material). A 3D printing system can mix appropriate types of self-healing material with solid-state battery component material for applications based on deterioration cycling information or other trends.

An appropriate proportion of self-healing materials (e.g., relative to the solid-state electrolyte or other component material) can vary with position within the battery design. If any crack is detected on the solid-state electrolyte because of formation of a dendrite, etc., then self-healing material will be sufficient to heal the defect and/or reduce the probability of further propagation of the crack or development of the dendrite. Since the solid-state battery can be 3D printed, control of the type of materials is specific and can vary with position.

A new/updated battery design 112 will be provided with the self-healing material incorporated into the design. The new/updated battery design 112 can include a self-healing material proportion and distribution update. The self-healing material can be incorporated as layers of varying thickness of self-healing material/battery component, regions, such as, patches, spots or clusters of self-healing material within the battery component, regions of self-healing material within a matrix of the battery component, alternating layers of self-healing material and battery component, etc.

In block 116, the new design can be printed by an additive manufacturing process, e.g., 3D or 4D printing. A 3D printer can fabricate the battery with very specific patterns and configurations that can include any number of distributions and proportions of the self-healing material therein. The new design can be employed for testing or resimulation in block 120. For example, after every recharge cycle of the battery, the system 100 can scan the battery to review dendrite formation patterns or cracking. The data collected from this testing can be employed to update the training of the historical learning model 104.

In a further aspect, fabricated batteries can be evaluated to further train the historical model 104. If a crack or dendrites form, a self-healing process can be deployed in block 122. In block 124, the effectiveness of the self-healing on the crack on the solid-state electrolyte is evaluated, and this data can also be employed to update the training of the historical learning model 104. A determination is performed to find how many recharges can be permitted for the battery before progressive growth of dendrites or cracks can be reversed and no short circuits created for the battery. This data can also be used to update the training of the historical learning model 104.

Using one or more types of scanning methods, the system 100 will evaluate each battery in a battery pack, and can set a maximum recharge and discharge rate, so that, differential formation of dendrites (considering growth of dendrite and self-healing of crack) does not cause any short circuits. An evaluation process can evaluate individual batteries in the pack to adjust the maximum recharge and discharge rate accordingly based on the 3D printed materials used for ameliorating the battery and based upon output needs to the system being powered.

The system 100 can further select which battery is to be recharged and how much recharge will be permitted. The system 100 can identify a time needed for self-healing of the crack in the solid-state electrolyte, and can also measure how much self-healing has occurred over time, so that the battery can again be considered for a higher level of recharge and discharge rate. The system 100 can iterate over battery designs to optimize the battery design based on self-healing capabilities. The system 100 can retest or re-simulate the design in block 120 to further improve the design or repair the battery. The system 100 can be employed to redesign batteries for self-healing and monitor batteries with self-healing capabilities to maximize charge rate and extend battery life.

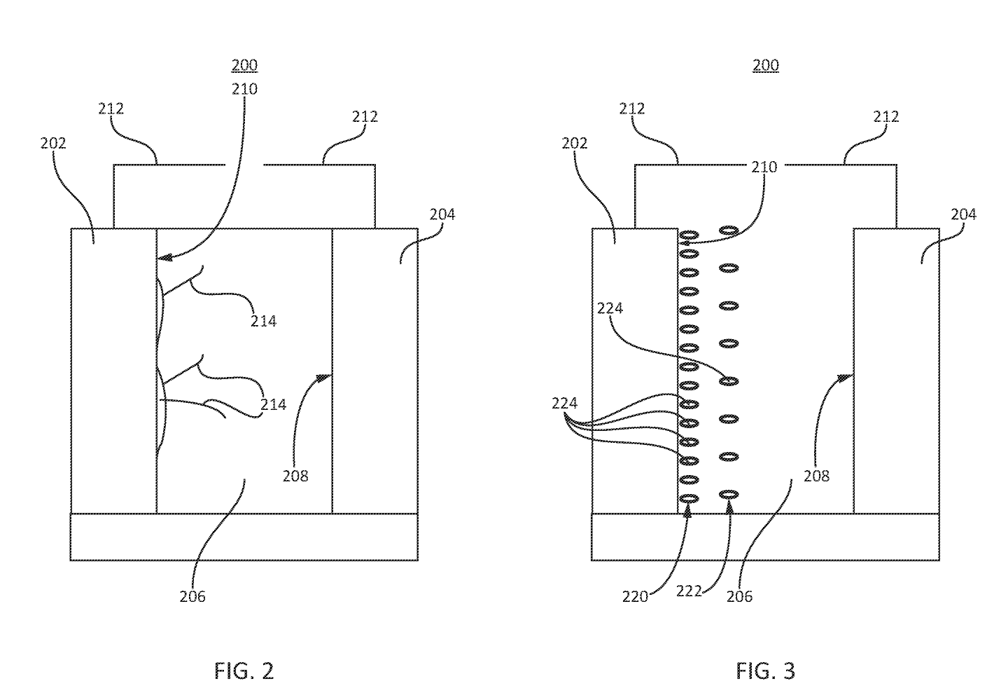

Referring to FIG. 2, a solid-state battery 200 includes an anode 202, a cathode 204, a solid-state electrolyte 206, an electrolyte/anode interface 210, an electrolyte/cathode interface 208 and structural surroundings including terminals 212, mount structures and the like. In some embodiments, the cathode 204 (or positive electrode) can be made with the same compounds as a lithium-ion battery (e.g., lithium iron phosphate (LFP), lithium nickel manganese cobalt oxides (NMC), lithium ion manganese oxide (LMO), etc.). The solid-state electrolyte 206 can include a ceramic or solid polymer. The anode 202 (or negative electrode) can be made of lithium metal (pure lithium). Other materials and or combinations of these and other materials are also contemplated.

Internal short circuits caused by formation of lithium dendrites 214 are one of the reasons for battery failure. A Li-ion battery operating under abnormal conditions, such as overcharging or lower temperature charging, can lead to lithium dendrite growth or lithium plating. Lithium dendrites 214 are metallic microstructures that form on the negative electrode or anode 202 during the charging process. Lithium dendrites 214 are formed when extra lithium ions accumulate on the electrolyte/anode interface 210 (anode surface) and cannot be absorbed into the anode 202 in time. Lithium dendrites 214 and cracks or other defects form and begin to propagate across the solid-state electrolyte 206.

Referring to FIG. 3, since cracks or dendrites 214 in the solid-state battery 200 can lead to failure of the battery, self-healing features are provided in accordance with embodiments of the present invention. In an example embodiment, self-healing material 224 is printed (e.g., 3D printed) within a matrix of battery component material, here, solid state electrolyte 206, during formation of the battery 200. The self-healing material 224 is distributed in accordance with predicted defect mapping. In FIG. 2, it can be seen that dendrites 214 form along the electrolyte/anode interface 210. As such, in accordance with historical learning, a proportion and distribution of the self-healing material 224 is arranged within the material of the solid-state electrolyte to prevent or reduce cracking or dendrite formation using self-healing. Since the origin of damage is likely to begin at the electrolyte/anode interface 210, the self-healing material 224 is more densely distributed in a first layer 220 then in a second layer 222. The self-healing material 224 can include self-healing polymers or elastomers, cementitious materials, metals, ceramics or any other printable materials with self-healing properties capable of reducing or eliminating cracking or dendrite formation in battery components through self-healing.

The self-healing material 224 can include material that can extrinsically or intrinsically heal damage. In an example, an extrinsic system can include microcapsules or vascular networks which, after material damage or cracking, the microcapsules fracture and release content into the crack to restore strength and allow restoration of material properties. An intrinsic system can include materials that need a trigger to begin healing. The material is able to restore its integrity by an external trigger for the healing to take place (such as thermo-mechanical, electrical, etc.).

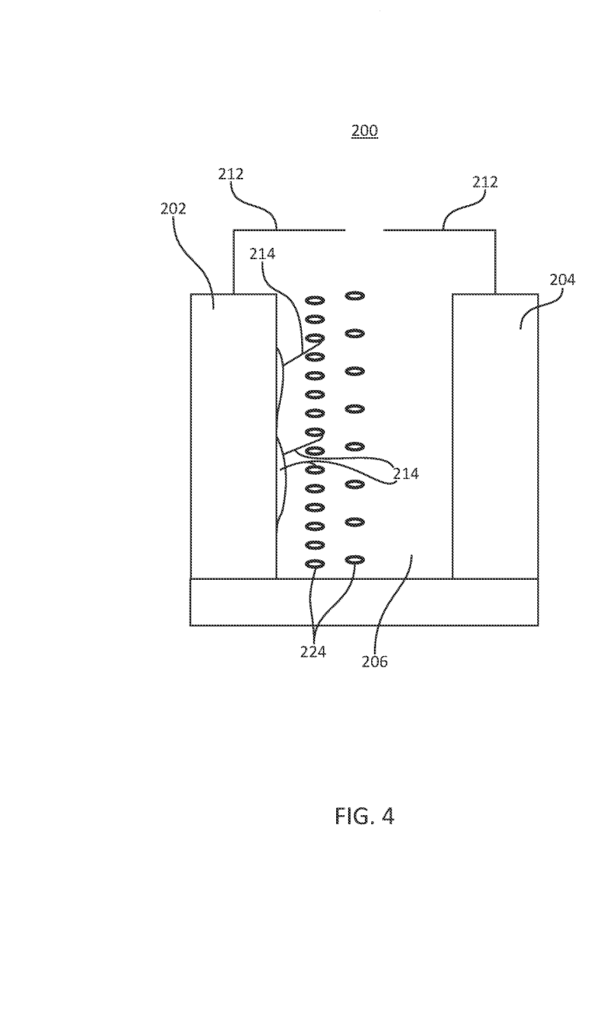

Referring to FIG. 4, the self-healing material 224 of the solid-state battery 200 chemically and/or mechanically reacts to stem the growth or even reverse defects, e.g., dendrite 214 or cracks, within the solid-state battery 200. The 3D printer has used appropriately placed spots of the self-healing material 224 within the solid-state electrolyte 206, so that the battery can be self-healed by letting the battery 200 rest for a period between recharges. In other embodiments, heat, charge or other trigger can be employed to initiate self-healing. Crack and dendrite propagation can be prevented and better performance and extended battery life can be achieved. In other embodiments, proportions of self-healing material 224 and the solid-state electrolyte 206 can be mixed together a uniformly applied (printed).

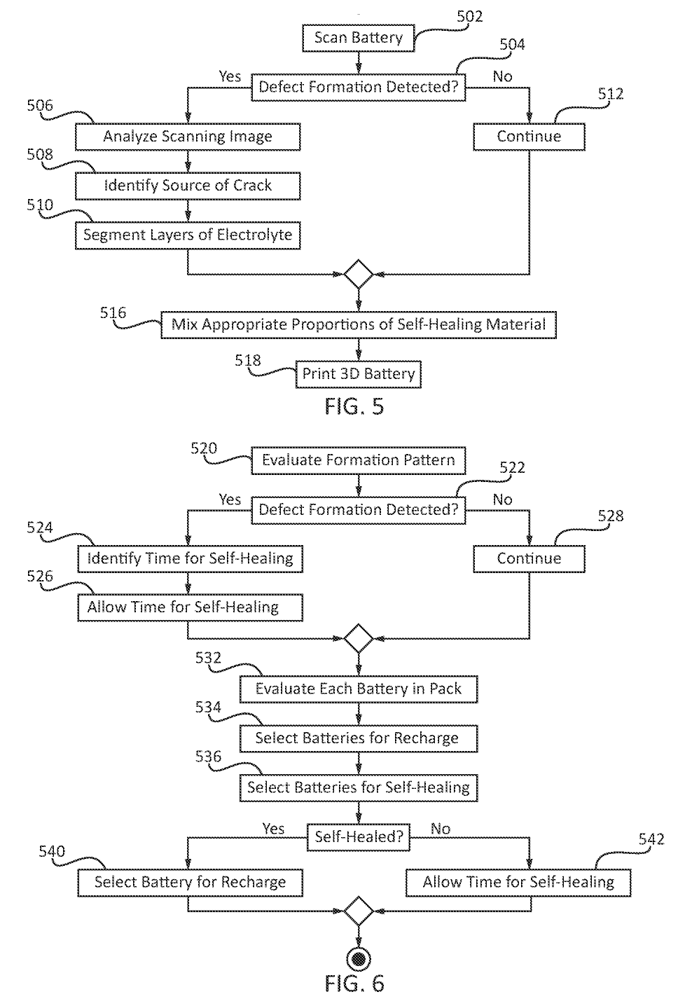

Referring to FIG. 5, a flow diagram shows an illustrative method for self-healing batteries in accordance with embodiments of the present invention. In a first stage, batteries are analyzed. In block 502, batteries that are in service can be scanned. In an embodiment, scanning capabilities can include X-rays, ultrasound, manual measurements or any other method for measuring a state of a battery. For example, a scanning module can be employed to validate an internal structure of the battery and how that structure changes after every recharge. Ultrasound or X-ray images of the batteries can be obtained to identify any growth pattern of dendrites in the battery. The scanning module can include a measure of battery performance and performance degradation can be employed as an indication of crack or dendrite formation. The system scans the batteries, and based on historical data, the system can identify a pattern or patterns of dendrite formation and the severity of any cracks.

In block 504, a detection of defects (e.g., dendrite and/or crack formation) is determined. Images of the scan or scans are analyzed in block 506 by analyzing the scanned image of the internal structure of the battery to identify how the battery is generating a defect. A dimension of crack will be identified as well as its source location and how it is propagated through, e.g., the solid-state electrolyte. Historical learning can be employed to identify the source of crack generation and how it propagates. Data can be gathered from various types of solid-state batteries where dendrite formation and crack formation patterns have been discovered to provide a crack formation model.

If dendrites or cracks are detected, their positions are located within the battery in block 508. The battery is segmented into regions in block 510 so that each region can be addressed. In block 512, this process is continued for all segments of the battery until all defects are covered.

In a next stage, batteries are fabricated in accordance with the analysis in the first stage. In block 516, an appropriate proportion of seal-healing material and battery component material is determined. The appropriate proportion includes a manner of distributing the self-healing material as well. The battery specifications, e.g., material specification of cathode, anode, electrolyte, gap between cathode and anode or thickness of solid-state electrolyte, are considered.

Based on a crack formation pattern, one or more types of self-healing material can be selected. The self-healing material can include, e.g., a material that grows on its own when any space is detected, or is exposed to the outside environment (e.g., oxygen).

In an embodiment, based on the crack formation pattern, appropriate types of self-healing material can be mixed in proportion with solid-state battery material. The solid-state battery material and self-healing battery material can be mixed in a mixing chamber of a 3D printing system. In other embodiments, self-healing material can be placed in layers or in an intermittent patch distribution within the battery material matrix.

In block 518, the solid-state battery is 3D printed with an appropriate combination of solid-state battery material and the self-healing battery material. A 3D printing system creates a solid-state battery with an appropriate combination of solid-state battery material and self-healing battery material. During printing, adjustments can be made based on identified locations of crack sources. Different segments (segmented layers from block 510) or different layers can have different proportions of self-healing material.

Referring to FIG. 6, fabricated batteries are evaluated and can be self-healed in accordance with embodiments of the present invention. In block 520, self-healing batteries are evaluated in service or any time after fabrication. In an example, batteries will be part of a battery pack, e.g., in an electric vehicle battery pack. While the batteries are in operation, an evaluation of defect formation patterns can be performed, e.g., on the anode, and it can be determined how the self-healing is progressing. In block 524, a time to self-heal can be identified based on the nature of the defect. For example, a crack propagating the solid-state electrolyte can be monitored and the battery can be removed from service to permit adequate time for self-healing in block 526. Self-healing can also be determined based on battery performance measurements.

The defect can be checked over time, and if the defect persists the process can be continued in block 528 until the defect heals. In block 532, each battery in the battery pack is evaluated to identify which batteries can be recharged and which batteries should have recharging reduced until self-healing is performed or completed. In block 534, within any battery pack, batteries are selected for recharge. Some batteries may be recharged while some batteries may need to be kept out of service for self-healing in block 536. A determination as to whether a battery has self-healed is made in block 538. Once the battery is self-healed, then that battery can be selected for recharging in block 540. Otherwise, sufficient time needs to be permitted to elapse to ensure the batteries are self-healed and can also be used for recharging in block 542. This allows the self-healing material to fill in any cracks and prevent any further dendrite formation.

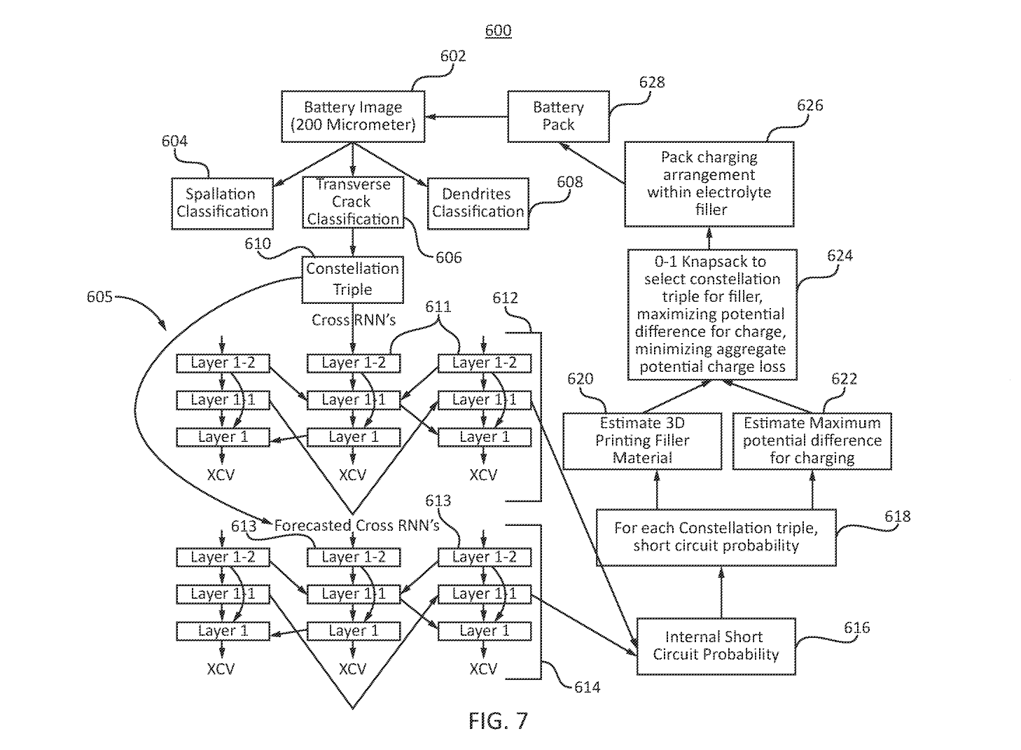

Referring to FIG. 7, an exemplary architecture 600 is shown for historical learning and self-healing processing in accordance with an embodiment. The architecture 600 for self-healing batteries includes acquiring battery images, in block 602, for a battery cell within a pack of batteries. In an embodiment, the image scale can be about a 200 micrometers resolution, although other image resolutions are contemplated. The image is then applied to a Convolutional Neural Network (CNN) 605 that discovers defects. In this example, each of spallation in block 604, transverse cracks in block 606, and dendrite formation in block 608 are considered and any defect in the image is set within bounding boxes that encapsulate the defects within the image. K-nearest neighbor is applied to each of the classifications to form constellation triples in block 610. This occurs several times over a sampling rate that can be, e.g., configured by an administrator.

Each of the constellation triples is indexed over time such that the bounding boxes can be forecasted out to after a next charging cycle. The instantaneous constellations are passed into a cross residual neural network (RNN) 612 that relates properties of each elemental triple constellation based on a second to last layer of the CNN 605. Cross weights or values (XCV) are passed to each layer to influence a probability of an internal short circuit. Forecasted constellation triples are also fed into a forecasted cross RNN 614.

Next, the cross RNN 612 and forecasted cross RNN 614, each output an internal short circuit probability. The two probabilities are averaged together to provide an overall internal short circuit probability in block 616.

In block 618, a short circuit probability is determined for each constellation triple. In block 620, multiple regression functions can be applied to provide an estimate of 3D filler for each constellation. The sum of the 3D filler provides the amount of material for a battery cell. Another multiple regression function estimates a maximum potential difference a cell can handle given the total constellation properties in block 622. A 0-1 Knapsack problem is performed, in block 624, where a maximum amount of 3D filler is established by the amount the 3D printer can create and which constellations are chosen for self-healing. The overall problem maximizes a potential difference across battery cells while minimizing charge loss.

In block 626, in an embodiment, a pack charging arrangement can be determined for a pack of batteries 628 which considers the 3D printing filler applied with self-healing materials. The pack charging arrangement can determine the maximum recharge and discharge rate, and set the rate accordingly. Each battery in the pack is evaluated and adjustments to the maximum recharge and discharge rate are determined accordingly. The pack charging arrangement can also identify how much time is needed for the self-healing process to complete for batteries in the pack under a given set of circumstances and adjusts the recharge rate to ensure the batteries are safe and reliable for future usage. The pack charging arrangement will also update the knowledge corpus with new data.

The exemplary neural network architecture 600 shown may be used to implement parts of the present systems, such as a historical learning model. A neural network is a generalized system that improves its functioning and accuracy through exposure to additional empirical data. The neural network becomes trained by exposure to the empirical data. During training, the neural network stores and adjusts a plurality of weights that are applied to the incoming empirical data. By applying the adjusted weights to the data, the data can be identified as belonging to a particular predefined class from a set of classes or a probability that the input data belongs to each of the classes can be output.

The empirical data, also known as training data, from a set of examples can be formatted as a string of values and fed into the input of the neural network. Each example may be associated with a known result or output. Examples can include solid-state batteries having particular failure modes being associated with countermeasures, shock and vibration response features associated with countermeasures, etc. Each example can be represented as a pair, (x, y), where x represents the input data and y represents the known output. The input data may include a variety of different data types, and may include multiple distinct values. The network can have one input node for each value making up the example’s input data, and a separate weight can be applied to each input value. The input data can, for example, be formatted as a vector, an array, or a string depending on the architecture of the neural network being constructed and trained.

The neural network “learns” by comparing the neural network output generated from the input data to the known values of the examples, and adjusting the stored weights to minimize the differences between the output values and the known values. The adjustments may be made to the stored weights through back propagation, where the effect of the weights on the output values may be determined by calculating the mathematical gradient and adjusting the weights in a manner that shifts the output towards a minimum difference. This optimization, referred to as a gradient descent approach, is a non-limiting example of how training may be performed. A subset of examples with known values that were not used for training can be used to test and validate the accuracy of the neural network.

During operation, the trained neural network can be used on new data that was not previously used in training or validation through generalization. The adjusted weights of the neural network can be applied to the new data, where the weights estimate a function developed from the training examples. The parameters of the estimated function which are captured by the weights are based on statistical inference.

In layered neural networks, nodes are arranged in the form of layers. An exemplary simple neural network can include nodes and has an input layer of source nodes, and a single computation layer having one or more computation nodes that also act as output nodes, where there is a single computation node for each possible category into which the input example could be classified. An input layer can have a number of source nodes equal to the number of data values in the input data. The data values in the input data can be represented as a column vector. Each computation node in the computation layer generates a linear combination of weighted values from the input data fed into nodes of the input layer, and applies a non-linear activation function that is differentiable to the sum. The exemplary simple neural network can perform classification on linearly separable examples (e.g., patterns).

A deep neural network, such as a multilayer perceptron, can have a plurality of nodes 611, 613 and include an input layer of source nodes, one or more computation layer(s) having one or more computation nodes, and an output layer, where there is a single output node for each possible category into which the input example could be classified. An input layer can have a number of source nodes equal to the number of data values in the input data. The computation nodes in the computation layer(s) can also be referred to as hidden layers, because they are between the source nodes and output node(s) and are not directly observed. Each node in a computation layer generates a linear combination of weighted values from the values output from the nodes in a previous layer, and applies a non-linear activation function that is differentiable over the range of the linear combination. The weights applied to the value from each previous node can be denoted, for example, by w₁, w₂, … w_{n-1,} wₙ. The output layer provides the overall response of the network to the input data. A deep neural network can be fully connected, where each node in a computational layer is connected to all other nodes in the previous layer, or may have other configurations of connections between layers. If links between nodes are missing, the network is referred to as partially connected.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment ("CPP embodiment" or “CPP”) is a term used in the present disclosure to describe any set of one, or more, storage media (also called "mediums") collectively included in a set of one, or more, storage devices that collectively include machine readable code corresponding to instructions and/or data for performing computer operations specified in a given CPP claim. A "storage device" is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

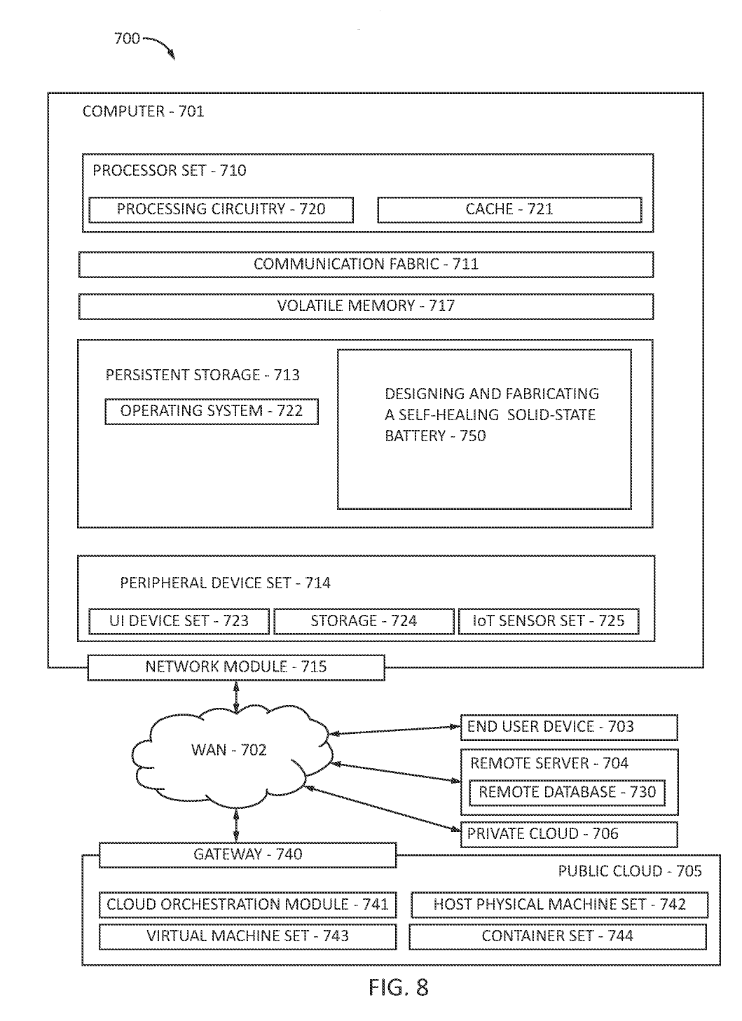

Referring to FIG. 8, a computing environment 700 contains an example of an environment for the execution of at least some of the computer code involved in performing the inventive methods, such as designing and fabricating a self-healing solid-state battery 750. In addition to block 750, computing environment 700 includes, for example, computer 701, wide area network (WAN) 702, end user device (EUD) 703, remote server 704, public cloud 705, and private cloud 706. In this embodiment, computer 701 includes processor set 710 (including processing circuitry 720 and cache 721), communication fabric 711, volatile memory 712, persistent storage 713 (including operating system 722 and block 750, as identified above), peripheral device set 714 (including user interface (UI) device set 723, storage 724, and Internet of Things (IoT) sensor set 725), and network module 715. Remote server 704 includes remote database 730. Public cloud 705 includes gateway 740, cloud orchestration module 741, host physical machine set 742, virtual machine set 743, and container set 744.

COMPUTER 701 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 730. As is well understood in the art of computer technology, and depending upon the technology, performance of a computer-implemented method may be distributed among multiple computers and/or between multiple locations. On the other hand, in this presentation of computing environment 700, detailed discussion is focused on a single computer, specifically computer 401, to keep the presentation as simple as possible. Computer 701 may be located in a cloud, even though it is not shown in a cloud in FIG. 8. On the other hand, computer 701 is not required to be in a cloud except to any extent as may be affirmatively indicated.

PROCESSOR SET 710 includes one, or more, computer processors of any type now known or to be developed in the future. Processing circuitry 720 may be distributed over multiple packages, for example, multiple, coordinated integrated circuit chips. Processing circuitry 720 may implement multiple processor threads and/or multiple processor cores. Cache 721 is memory that is located in the processor chip package(s) and is typically used for data or code that should be available for rapid access by the threads or cores running on processor set 710. Cache memories are typically organized into multiple levels depending upon relative proximity to the processing circuitry. Alternatively, some, or all, of the cache for the processor set may be located “off chip.” In some computing environments, processor set 710 may be designed for working with qubits and performing quantum computing.

Computer readable program instructions are typically loaded onto computer 701 to cause a series of operational steps to be performed by processor set 710 of computer 701 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 721 and the other storage media discussed below. The program instructions, and associated data, are accessed by processor set 710 to control and direct performance of the inventive methods. In computing environment 700, at least some of the instructions for performing the inventive methods may be stored in block 750 in persistent storage 713.

COMMUNICATION FABRIC 711 is the signal conduction path that allows the various components of computer 701 to communicate with each other. Typically, this fabric is made of switches and electrically conductive paths, such as the switches and electrically conductive paths that make up buses, bridges, physical input / output ports and the like. Other types of signal communication paths may be used, such as fiber optic communication paths and/or wireless communication paths.

VOLATILE MEMORY 712 is any type of volatile memory now known or to be developed in the future. Examples include dynamic type random access memory (RAM) or static type RAM. Typically, volatile memory 712 is characterized by random access, but this is not required unless affirmatively indicated. In computer 701, the volatile memory 712 is located in a single package and is internal to computer 701, but, alternatively or additionally, the volatile memory may be distributed over multiple packages and/or located externally with respect to computer 701.

PERSISTENT STORAGE 713 is any form of non-volatile storage for computers that is now known or to be developed in the future. The non-volatility of this storage means that the stored data is maintained regardless of whether power is being supplied to computer 701 and/or directly to persistent storage 713. Persistent storage 713 may be a read only memory (ROM), but typically at least a portion of the persistent storage allows writing of data, deletion of data and re-writing of data. Some familiar forms of persistent storage include magnetic disks and solid state storage devices. Operating system 722 may take several forms, such as various known proprietary operating systems or open source Portable Operating System Interface-type operating systems that employ a kernel. The code included in block 750 typically includes at least some of the computer code involved in performing the inventive methods.

PERIPHERAL DEVICE SET 714 includes the set of peripheral devices of computer 701. Data communication connections between the peripheral devices and the other components of computer 701 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 723 may include components such as a display screen, speaker, microphone, wearable devices (such as goggles and smart watches), keyboard, mouse, printer, touchpad, game controllers, and haptic devices. Storage 724 is external storage, such as an external hard drive, or insertable storage, such as an SD card. Storage 724 may be persistent and/or volatile. In some embodiments, storage 724 may take the form of a quantum computing storage device for storing data in the form of qubits. In embodiments where computer 401 is required to have a large amount of storage (for example, where computer 701 locally stores and manages a large database) then this storage may be provided by peripheral storage devices designed for storing very large amounts of data, such as a storage area network (SAN) that is shared by multiple, geographically distributed computers. IoT sensor set 725 is made up of sensors that can be used in Internet of Things applications. For example, one sensor may be a thermometer and another sensor may be a motion detector.

NETWORK MODULE 715 is the collection of computer software, hardware, and firmware that allows computer 701 to communicate with other computers through WAN 702. Network module 715 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 715 are performed on the same physical hardware device. In other embodiments (for example, embodiments that utilize software-defined networking (SDN)), the control functions and the forwarding functions of network module 715 are performed on physically separate devices, such that the control functions manage several different network hardware devices. Computer readable program instructions for performing the inventive methods can typically be downloaded to computer 701 from an external computer or external storage device through a network adapter card or network interface included in network module 715. WAN 702 is any wide area network (for example, the internet) capable of communicating computer data over non-local distances by any technology for communicating computer data, now known or to be developed in the future. In some embodiments, the WAN 702 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 703 is any computer system that is used and controlled by an end user (for example, a customer of an enterprise that operates computer 701), and may take any of the forms discussed above in connection with computer 701. EUD 703 typically receives helpful and useful data from the operations of computer 701. For example, in a hypothetical case where computer 701 is designed to provide a recommendation to an end user, this recommendation would typically be communicated from network module 715 of computer 701 through WAN 702 to EUD 703. In this way, EUD 703 can display, or otherwise present, the recommendation to an end user. In some embodiments, EUD 703 may be a client device, such as thin client, heavy client, mainframe computer, desktop computer and so on.

REMOTE SERVER 704 is any computer system that serves at least some data and/or functionality to computer 701. Remote server 704 may be controlled and used by the same entity that operates computer 701. Remote server 704 represents the machine(s) that collect and store helpful and useful data for use by other computers, such as computer 701. For example, in a hypothetical case where computer 701 is designed and programmed to provide a recommendation based on historical data, then this historical data may be provided to computer 701 from remote database 730 of remote server 704.

PUBLIC CLOUD 705 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 705 is performed by the computer hardware and/or software of cloud orchestration module 741. The computing resources provided by public cloud 705 are typically implemented by virtual computing environments that run on various computers making up the computers of host physical machine set 742, which is the universe of physical computers in and/or available to public cloud 705. The virtual computing environments (VCEs) typically take the form of virtual machines from virtual machine set 743 and/or containers from container set 744. It is understood that these VCEs may be stored as images and may be transferred among and between the various physical machine hosts, either as images or after instantiation of the VCE. Cloud orchestration module 741 manages the transfer and storage of images, deploys new instantiations of VCEs and manages active instantiations of VCE deployments. Gateway 740 is the collection of computer software, hardware, and firmware that allows public cloud 705 to communicate through WAN 702. Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 706 is similar to public cloud 705, except that the computing resources are only available for use by a single enterprise. While private cloud 706 is depicted as being in communication with WAN 702, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 705 and private cloud 706 are both part of a larger hybrid cloud.

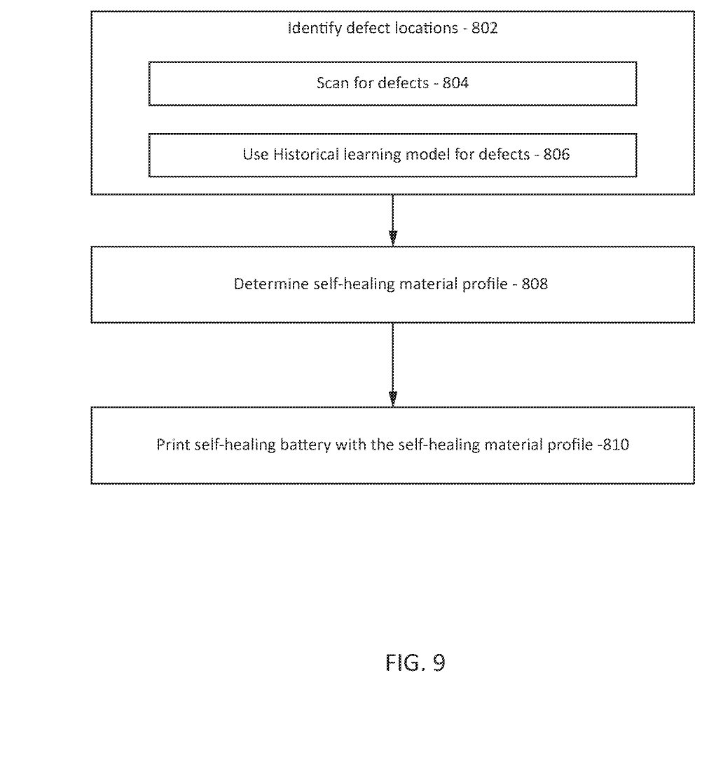

Referring to FIG. 9, a system/computer-implemented method for fabricating a self-healing solid state battery is shown. In block 802, locations are identified in a solid-state battery where defects are likely to occur. This can include scanning a solid-state battery with penetrating energy to locate defects in block 804. The information gathered can be employed to train a historical learning system. In block 806, the historical learning model can be employed to predict defects or trends to discover locations where defects will likely originate. Defects can include cracks, dendrite formation, spallation, etc. Locations can also be identified from past battery designs.

In block 808, a self-healing material profile is determined relative to solid-state battery component material to counter defect growth in the locations. In an embodiment, given the battery design, use and specification, the historical learning model can be consulted to determine the self-healing material profile. The self-healing material profile can include increased self-healing material at interfaces where cracking and dendrite formation is likely to occur. For example, a higher density of self-healing material can be employed at the anode/solid-state electrolyte material interface. The density can decrease with distance from the anode/solid-state electrolyte material interface. The self-healing material profile can include a distribution of self-healing material in regions within a matrix of the solid-state battery component material. Regions can include clusters, patches, spots or other geometrical shapes or self-healing material within the matrix of the solid-state battery component material (e.g., the solid-state electrolyte).

The self-healing material profile can include a proportion of self-healing material and the solid-state battery component material. The materials can be mixed together before or during 3D printing of the solid-state battery includes mixing the self-healing material and the solid-state battery component material together in accordance with the proportion.

In block 810, the solid-state battery is printed in accordance with the self-healing material profile. The solid-state battery can self-heal. In an embodiment, the self-healing can occur by permitting a rest period from operation.

As employed herein, the term “hardware processor subsystem” or “hardware processor” can refer to a processor, memory, software or combinations thereof that cooperate to perform one or more specific tasks. In useful embodiments, the hardware processor subsystem can include one or more data processing elements (e.g., logic circuits, processing circuits, instruction execution devices, etc.). The one or more data processing elements can be included in a central processing unit, a graphics processing unit, and/or a separate processor- or computing element-based controller (e.g., logic gates, etc.). The hardware processor subsystem can include one or more on-board memories (e.g., caches, dedicated memory arrays, read only memory, etc.). In some embodiments, the hardware processor subsystem can include one or more memories that can be on or off board or that can be dedicated for use by the hardware processor subsystem (e.g., ROM, RAM, basic input/output system (BIOS), etc.).

In some embodiments, the hardware processor subsystem can include and execute one or more software elements. The one or more software elements can include an operating system and/or one or more applications and/or specific code to achieve a specified result.

In other embodiments, the hardware processor subsystem can include dedicated, specialized circuitry that performs one or more electronic processing functions to achieve a specified result. Such circuitry can include one or more application-specific integrated circuits (ASICs), FPGAs, and/or PLAs.

These and other variations of a hardware processor subsystem are also contemplated in accordance with embodiments of the present invention.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Having described preferred embodiments (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A computer-implemented method for fabricating a solid state battery, comprising:
identifying locations in a solid-state battery where defects are likely to occur;
determining a self-healing material profile relative to solid-state battery component material to counter defect growth in the locations; and
printing the solid-state battery in accordance with the self-healing material profile.

2. The method of claim 1, wherein identifying locations includes scanning a solid-state battery with penetrating energy to locate defects.

3. The method of claim 1, wherein determining the self-healing material profile includes increasing self-healing material at interfaces where cracking and dendrite formation is likely to occur.

4. The method of claim 1, wherein determining the self-healing material profile includes distributing self-healing material in regions within a matrix of the solid-state battery component material.

5. The method of claim 1, wherein determining the self-healing material profile includes determining a proportion of self-healing material and the solid-state battery component material.

6. The method of claim 5, wherein printing the solid-state battery includes mixing the self-healing material and the solid-state battery component material together in accordance with the proportion.

7. The method of claim 1, further comprising self-healing the solid-state battery by permitting a rest period from operation.

8. The method of claim 1, wherein identifying locations in the solid-state battery further comprises employing a historical learning model to predict defects.

9. A system for fabricating a solid state battery, comprising:
a hardware processor; and
a memory that stores a computer program which, when executed by the hardware processor, causes the hardware processor to:
identify locations in a solid-state battery where defects are likely to occur;
determine a self-healing material profile relative to solid-state battery component material to counter defect growth in the locations; and
print the solid-state battery in accordance with the self-healing material profile.

10. The system of claim 9, further comprising a penetrating energy scanner to scan a solid-state battery to locate defects.

11. The system of claim 9, wherein the self-healing material profile includes a higher proportion of self-healing material at interfaces where cracking and dendrite formation is likely to occur.

12. The system of claim 9, wherein the self-healing material profile includes a distribution of self-healing material in regions within a matrix of the solid-state battery component material.

13. The system of claim 9, wherein the self-healing material profile includes a proportion of self-healing material and the solid-state battery component material.

14. The system of claim 13, wherein the proportion includes a mixture of the self-healing material and the solid-state battery component material together in accordance with the proportion.

15. The system of claim 9, wherein the computer program causes the hardware processor to employ a historical learning model to predict defects.

16. A solid-state battery, comprising:
an anode;
a cathode; and
a solid-state electrolyte disposed between the anode and the cathode, the solid-state electrolyte including self-healing material to repair defects therein.

17. The battery of claim 16, wherein the self-healing material includes a higher density within the solid-state electrolyte at the anode.

18. The battery of claim 16, wherein the solid-state electrolyte includes a mixture of the self-healing material and solid-state electrolyte component material.

19. The battery of claim 16, wherein the solid-state electrolyte includes a distribution of self-healing material in regions within a matrix of the solid-state electrolyte.

20. The battery of claim 16, wherein the solid-state battery is printed in an additive manufacturing process.
